(19) United States
(12) Patent Application Publication
(10) Pub. No.: US 2017/0218206 A1
(43) Pub. Date: Aug. 3, 2017

(54) MULTILAYER COATING FILM AND COATED OBJECT

(71) Applicant: MAZDA MOTOR CORPORATION, Hiroshima (JP)

(72) Inventors: Takakazu YAMANE, Hiroshima-shi, Hiroshima (JP); Keiichi OKAMOTO, Hiroshima-shi, Hiroshima (JP); Kouji TERAMOTO, Hiroshima-shi, Hiroshima (JP)

(73) Assignee: MAZDA MOTOR CORPORATION, Hiroshima (JP)

(21) Appl. No.: 15/514,791

(22) PCT Filed: Nov. 2, 2015
(86) PCT No.: PCT/JP2015/005508

§ 371 Date: Mar. 27, 2017

(30) Foreign Application Priority Data
Dec. 2, 2014 (JP) 2014-244338

(51) Int. Cl. C09D 5/33; C09D 167/00; C09D 7/12; C09D 133/00; C23C 14/14; C23C 14/58

(52) U.S. Cl. CPC C09D 5/004; C23C 14/14; C23C 14/5886; C09D 7/1275; C09D 7/1216; C09D 133/00; C09D 167/00; C08K 2201/005; C08K 7/00

(57) ABSTRACT

A multilayer coating film 12 includes a bright layer 15 and a colored layer 16 superposed on the bright layer 15, the bright layer 15 including aluminum flakes 22, and the colored layer 16 including a black pigment 23 dispersed in the colored layer 16. The black pigment 23 in the colored layer 16 has a particle size distribution with a peak at a particle size of 200 nm or lower.

### TECHNICAL FIELD

The present invention relates to a multilayer coating film and a coated object.

### BACKGROUND ART

Generally, it has been attempted to apply a plurality of coating films on top of each other on a base surface of an automobile body or another automobile component in order to improve protection and appearance of the base. For example, Patent Document 1 discloses that a multilayer coating film is formed on top of an intermediate coating film of an automobile body. In this publication, it is disclosed how a metallic base coat, a mica base coat, and a transparent color coat are superposed one upon the other on the intermediate coating film in this order in order to obtain an easily reproducible coating film of a uniform appearance (coloring property). Moreover, this publication discloses the attempt to obtain similar colors—or at least a neighboring hue—according to the hue circle of the Munsell color system in the metallic base coat, mica base coat, and transparent color coat by defining a lightness L* value of 15°, which is based on these coats, within a predetermined range in order to obtain a coating film with an appearance of depth and an unprecedented impressive design.

### CITATION LIST

### Patent Documents

Patent Document 1: Japanese Unexamined Patent Publication No. 2008-126095

### SUMMARY OF THE INVENTION

### Technical Problem

The present invention attempts to develop a multilayer coating film of a brilliant grey color creating an effect of light and shade. In particular, the present invention attempts to develop a grey color which is not perceived as a mixture of chromatic colors but which creates the impression of a transparent metallic texture (metallic grey).

More specifically, in a metallic coat where a transparent clear coat is provided on top of a metallic base, which includes a conventional pigment and bright material, each of the bright material particles reflects light. Thus, the coat appears grainy, which makes it difficult to obtain the impression of a metallic texture which looks like a freshly polished metallic surface. Further, carbon black, which is conventionally used as a black pigment to obtain a grey color, does not fully absorb light at all wavelengths: compared to the absorption coefficient of wavelengths ranging from blue to violet, the absorption coefficient of wavelengths ranging from red to yellow is relatively low. Therefore, a coating film which includes carbon black as a black pigment has a slight tinge of red or yellow. Furthermore, the impression of a transparency is weakened as a consequence of the pigment reflecting light irregularly. Moreover, white blur occurs when the coating film is viewed obliquely—i.e., in shade—and does not permit the impression of a sharp metallic texture. That is, the effect of light and shade (highlights (light) and shade (dark) when hit by light) becomes weaker.

Conventional approaches were not able offer an effective countermeasure to address the tinge of red or yellow, the weakened impression of a transparency, and the white blur. Thus it was problematic to develop a grey color which creates the impression a vivid, transparent metallic texture.

### Solution to the Problem

The inventors have found a solution for the above problem by controlling the particle size of the black pigment.

The multilayer coating film disclosed herein is a multilayer coating film in which a translucent colored layer including a black pigment dispersed in the translucent colored layer is superposed on a bright layer. The black pigment in the colored layer has a particle size distribution with a peak at a particle size of 200 nm or lower.

According to this multilayer coating film, a grey color develops through the coloring effect of the black pigment in the colored layer, and through the reflection of light, which has passed through the colored layer, from the bright layer. The density of the grey color changes depending on the concentration of the black pigment in the colored layer. In order to obtain a lightness of 6 to 50 (L* value), however, it is beneficial if the black pigment has a concentration ranging from 0.1% by mass to 0.5% by mass inclusive, and even more beneficial if the black pigment has a concentration ranging from 0.2% by mass to 0.4% by mass inclusive. Here, a spectrophotometer (e.g., MA98 Multi-Angle Spectrophotometer by X-Rite Inc.) specified by the Japanese Industrial Standard JIS Z 8722 is used to measure the L* value (45°) at an angle of illumination of 45 degrees and at an angle of light reception departing 45 degrees from a specular reflection angle (perpendicular light reception). The “45° ” in “L* value)(45° ” stands for the angle of light reception (same below).

In this manner, a black pigment, which has a particle size distribution with a peak at a particle size of 200 nm or lower, is employed in the colored layer. This reduces irregular reflection and allows the multilayer coating film to develop a grey color which is not perceived as a mixture of chromatic colors, but which creates the impression of a transparent metallic texture.

In the present invention, a pigment particle size d is a particle size of a dispersoid distributed in a coating film. Carbon black, for example, has primary particles which agglomerate to form structures. Further, the structures mechanically entangle and form groups. The pigment particle size d refers to the particle size of the structures or the groups. This pigment particle size d (average length and width) is measured by observing the structures or the groups through an electron microscope. In a structure 1, which is exemplified in FIG. 1, “2” is a primary particle, “L” is the length of the structure, and “M” is the width of the structure.

Next, the effects of refining the black pigment will be described.

It is known that carbon black, which is used as black pigment, has a lower absorption coefficient for red light beams than for blue light beams. As exemplified in FIG. 2, the visible light transmission of a coating film employing conventional carbon black features a high transmittance in the red wavelength range (λ=610-750 nm). Moreover, the smaller the particle size d of carbon black is, the higher the absorption coefficient becomes. On the other hand, it is known that Rayleigh scattering is likely to occur if the particle size d becomes significantly smaller than a light wavelength λ, i.e., if (π·d/λ)<1.

For example, if the carbon black has a particle size d of approximately 200 nm, the carbon black absorbs fewer blue light beams than red light beams. In addition, as schematically shown in FIG. 3, many red light beams (wavelength of λ=610-750 nm) are irregularly reflected due to the Rayleigh scattering caused by each individual pigment particle 1. On the other hand, since blue light beams have a short wavelength (λ, =435˜480 nm), Rayleigh scattering does not occur if the particle size d is approximately 200 nm. Therefore, a coating film which includes a high amount of carbon black with a particle size d of approximately 200 nm develops a tinge of red.

If, by contrast, the black pigment has a particle size d of, e.g., 150 nm, the scattering of red light beams can be significantly reduced since the scattering coefficient ks is proportional to d⁶/λ⁴, as can be seen in the Rayleigh scattering equation shown below. More specifically, if the particle size d is small, the absorption coefficient of the carbon black becomes high. In addition, as schematically shown in FIG. 4, since the scattering of red light beams due to the pigment particles 1 can be significantly reduced, the risk of the coating film developing a red color can be reduced.

Rayleigh Scattering Equation

ks=[2π⁵/3]×n×[(m²−1)/(m²+2)]²×[d⁶/λ⁴]

where “n” is the number of particles, and “m” is the reflection coefficient.

Here, the black pigment has a particle size distribution with a peak at a particle size of 200 nm or lower, which means that a large proportion of the black pigment has a particle size of 200 nm or lower. Consequently, an increased proportion of the black pigment having a particle size of 200 nm or lower can reduce Rayleigh scattering of red light beams and the risk of the multilayer coating film developing a tinge of red.

In addition, according to the present invention, by reducing Rayleigh scattering as described above, the impression of transparency can be enhanced and white blur can be reduced.

As described above, if the black pigment has a small particle size d, Rayleigh scattering of red light beams can be reduced. On the other hand, Rayleigh scattering of blue light beams is likely to occur, which is why the multilayer coating film is at risk of developing a slight tinge of blue. Other than a tinge of red or yellow, however, a slight tinge of blue does not dull the color tone of grey.

Beneficially, the black pigment of the colored layer has a particle size distribution with a peak at a particle size of 180 nm or lower, and more beneficially at a particle size of 150 nm or lower. This reduces the development of red and yellow tinges, and is beneficial for developing a grey color which creates the impression of a transparent metallic texture.

Beneficially, carbon black is employed as the black pigment in the colored layer.

In order to increase the lightness of the multilayer coating film, it is beneficial if the bright layer is whitish or grayish. Further, a layer plated with, e.g., chrome, nickel, or aluminum, or a vapor-deposited layer may be employed as the bright layer. Beneficially, however, a coating film including a bright material may be employed. In order to increase brilliance and to create the impression of a metallic texture, it is beneficial to employ aluminum flakes, which are obtained by crushing aluminum foil, as the bright material. It is even more beneficial to employ vapor-deposited aluminum flakes, which are obtained by crushing an aluminum film vapor-deposited onto a thin base and which have a surface of an increased smoothness, as the bright material.

If employing the aluminum flakes as the bright material, it is beneficial if the bright material is superposed on a black base layer.

If the aluminum flakes are thin, light incident on the multilayer coating film passes through the aluminum flakes and is reflected from a base. In this case, the color of the base influences the appearance of the color of the coating film. Here, the base layer is black, which allows to obtain a desired metallic grey. This enhances the impression of density, depth, and metallic texture. In addition, a jet-black color, which occurs in shade, is intensified. For example on portions of a surface of a coated object which have a different angle or which are curved, the contrast of the color tone is enhanced, and a vivid appearance can be advantageously obtained.

It is beneficial if a transparent clear layer is superposed on the colored layer. This allows for improving resistance to acids, scuffing damage, and scratches.

The coated object provided with the multilayer coating film may be, for example, an automobile body or a motorcycle. The body of a different vehicle, or another metal article, may as well be provided with the multilayer coating film.

### Advantages of the Invention

According to the present invention, a multilayer coating film includes a colored layer, which includes a black pigment dispersed in the colored layer and is superposed on a bright layer. The black pigment in the colored layer has a particle size distribution with a peak at a particle size of 200 nm or lower. This allows the multilayer coating film to develop a brilliant grey color with an effect of light and shade. Particularly, the multilayer coating film develops a grey color (metallic grey) which is not perceived as a mixture of chromatic colors, but which creates the impression of a transparent metallic texture.

### BRIEF DESCRIPTION OF THE DRAWINGS

FIG. 1 shows a structure.

FIG. 2 shows visible light transmittance of a coating film which employs conventional carbon black as pigment.

FIG. 3 is a cross-sectional view schematically showing Rayleigh scattering in a coating film in the case of large pigment particles.

FIG. 4 is a cross-sectional view schematically showing how Rayleigh scattering is reduced in a coating film in the case of small pigment particles.

FIG. 5 is a cross-sectional view schematically showing an example multilayer coating film provided on a surface of a car body.

FIG. 6 is a graph schematically showing a particle size distribution in commercially available carbon black and in fine carbon black.

FIG. 7 is a graph schematically showing a particle size distribution in fine carbon black according to an example.

FIG. 8 is a graph showing spectral reflectance of a multilayer coating film according to the examples and a comparative example.

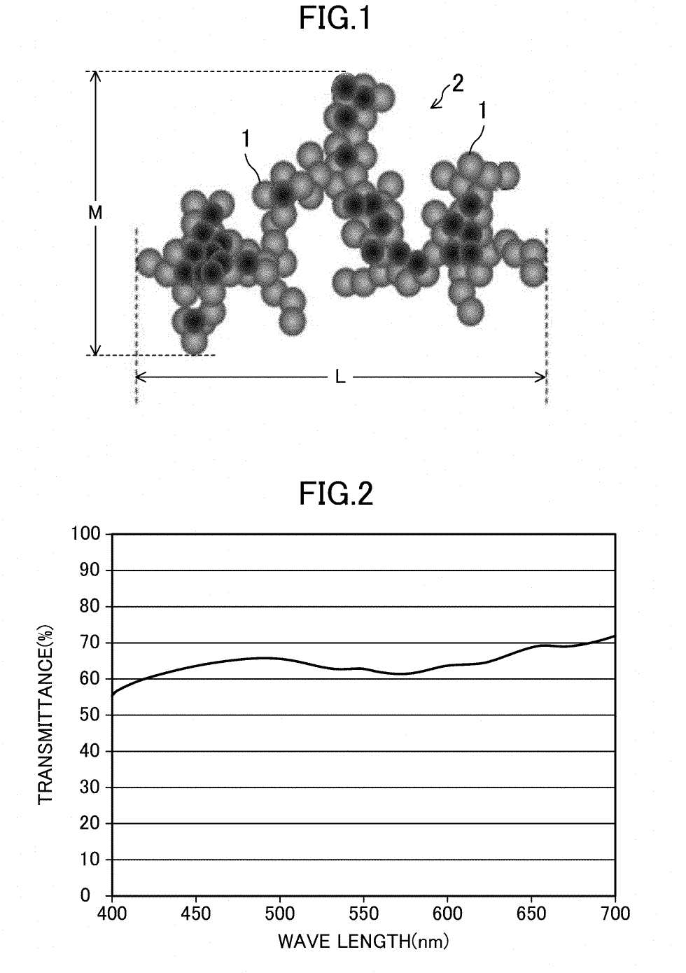

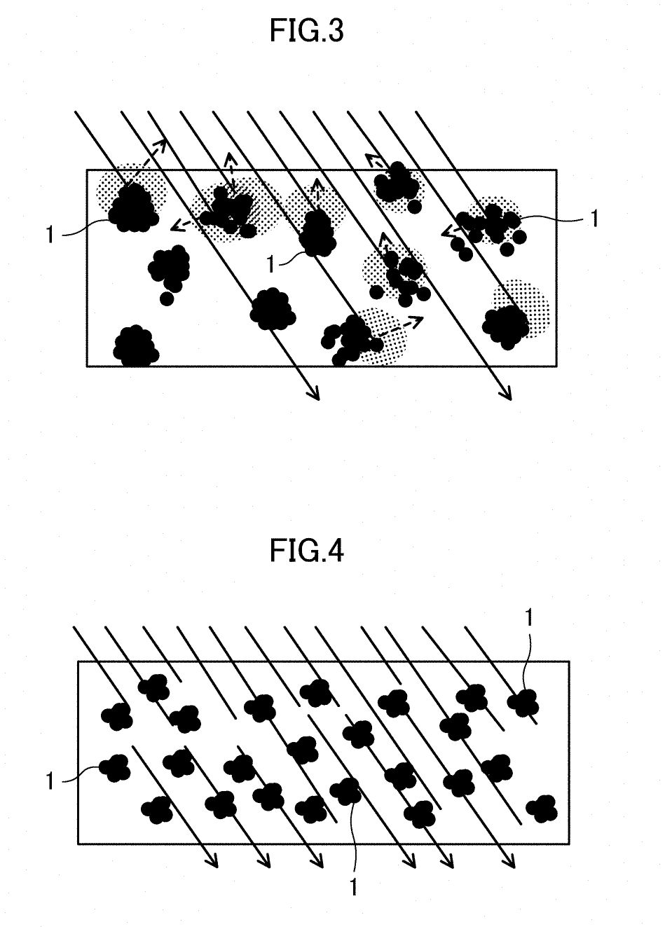

### DESCRIPTION OF EMBODIMENT

Embodiments of the present invention are described below with reference to the drawings. Note that the below embodiments are merely beneficial examples in nature, and are not intended to limit the scope, application, or uses of the present invention.

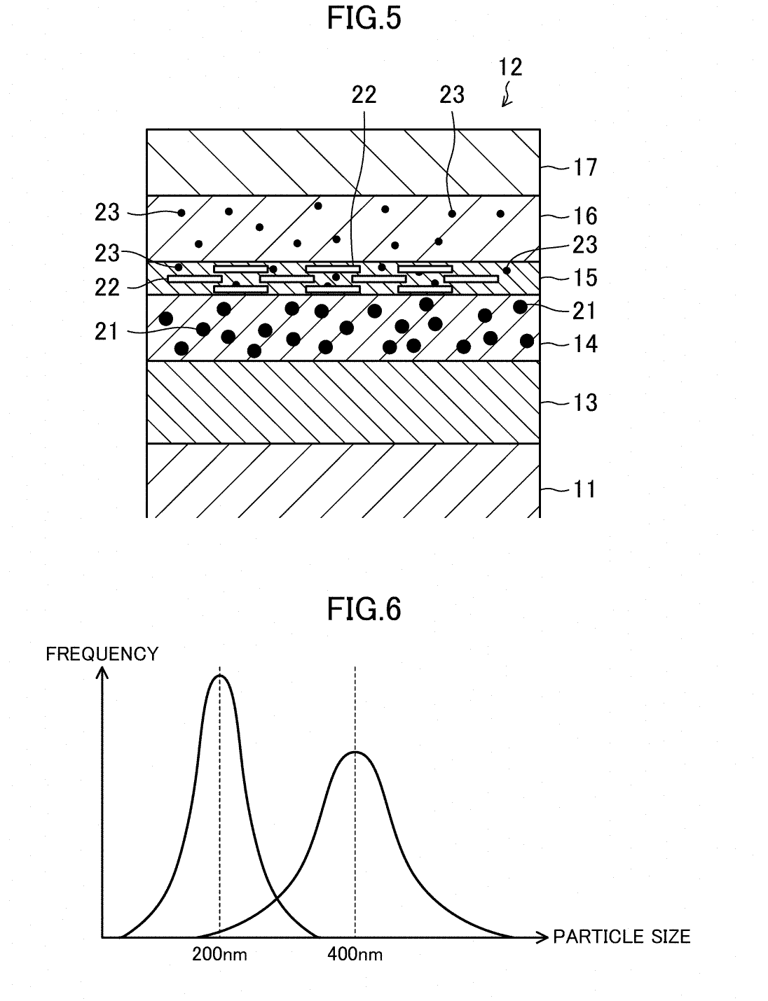

As shown in FIG. 5, a multilayer coating film 12 provided on a surface of an automobile body (steel plate) 11, contains a black base layer 14, a bright layer 15, a translucent colored layer (black) 16, and a transparent clear layer 17 which are superposed one upon the other in this order. An electrodeposition coating film (undercoat) 13 is formed on the surface of the automobile body 11 by cationic electrodeposition. The multilayer coating film 12 is provided on top of the electrodeposition coating film 13. In the multilayer coating film 12, the black base layer 14 corresponds to an intermediate coat, and the bright layer 15, the colored layer 16, and the transparent clear layer 17 correspond to a topcoat.

A first black pigment 21 is dispersed in the black base layer 14. Aluminum flakes 22, which serve as bright material, and a second black pigment 23 are dispersed in the bright layer 15. The second black pigment 23 is dispersed in the colored layer 16.

Commercially available carbon black, graphite, or iron (II, III) oxide may be employed as the first black pigment 21. It is beneficial to employ fine carbon black as the second black pigment 23.

As shown in FIG. 6, commercially available carbon black usually has a particle size distribution with a peak at a particle size ranging from 300 nm to 500 nm inclusive. The fine carbon black acting as the second black pigment 23 in the bright layer 15 and the colored layer 16 has a particle size distribution with a peak at a particle size of 200 nm or lower. It is beneficial if the fine carbon black has a small particle size. However, too small particles are prone to clump together (dispersion properties deteriorate), which is why it is advantageous if the peak particle size has a lower limit of, e.g., 50 nm.

Fine carbon black can be obtained by wet grinding commercially available carbon black using a grinding medium such as glass beads. By wet grinding, the structure of the carbon black is mechanically ground and obtains a small particle size.

In order to develop a grey color, the colored layer 16 has a pigment concentration (carbon black) ranging from 0.1% by mass to 0.5% by mass inclusive. The black base layer 14 serves as a black base, and thus has a pigment concentration ranging from, e.g., 1% by mass to 20% by mass inclusive.

The aluminum flakes 22 in the bright layer 15 are oriented to be substantially parallel with the surface of the bright layer. After having applied a coating, which includes the aluminum flakes 22 and the second black pigment 23, on top of the black base layer 14, a solvent included in the coating film is vaporized by stoving. As a result, the coating film shrinks in volume and becomes flat, and the aluminum flakes 22 arrange in a physically flat manner.

The black base layer 14 includes a resin component which may be, e.g., a polyester-based resin. The bright layer 15 and the colored layer 16 include a resin component which may be, e.g., an acrylic-based resin. The clear layer 17 includes a resin component which may be, e.g., an acid/epoxy-based cured acrylic resin.

### Examples and Comparative Example

### First Example

The composition of a multilayer coating film of a first example is shown in Table 1.

TABLE 1

| | | Solid | |
|---|---|---|---|
| | | Content | |
| Coating Film | | by Mass | Thickness |
| Layers | Resins and Other Components | (%) | (μm) |
| Transparent | Resin: Acid/Epoxy-Based Cured | 100 | 35 |
| Clear Layer | Acrylic Resin | | |
| Colored Layer | Resin: Acrylic-Based Resin | 99.7 | 10 |
| | Pigment: Fine Carbon Black | 0.3 | |
| | (Peak Particle Size: 180 nm) | | |
| Bright Layer | Resin: Acrylic-Based Resin | 68.0 | 2 |
| | Pigment: Fine Carbon Black | 7.0 | |
| | Bright Material: Vapor-Deposited | 25.0 | |
| | Aluminum Flakes | | |
| Base Layer | Resin: Polyester-Based Resin | 65.7 | 15 |
| | Pigment: Commercially Available | 7.1 | |
| | Carbon Black | | |
| | Extender Pigment: Barium Sulfate | 27.2 | |

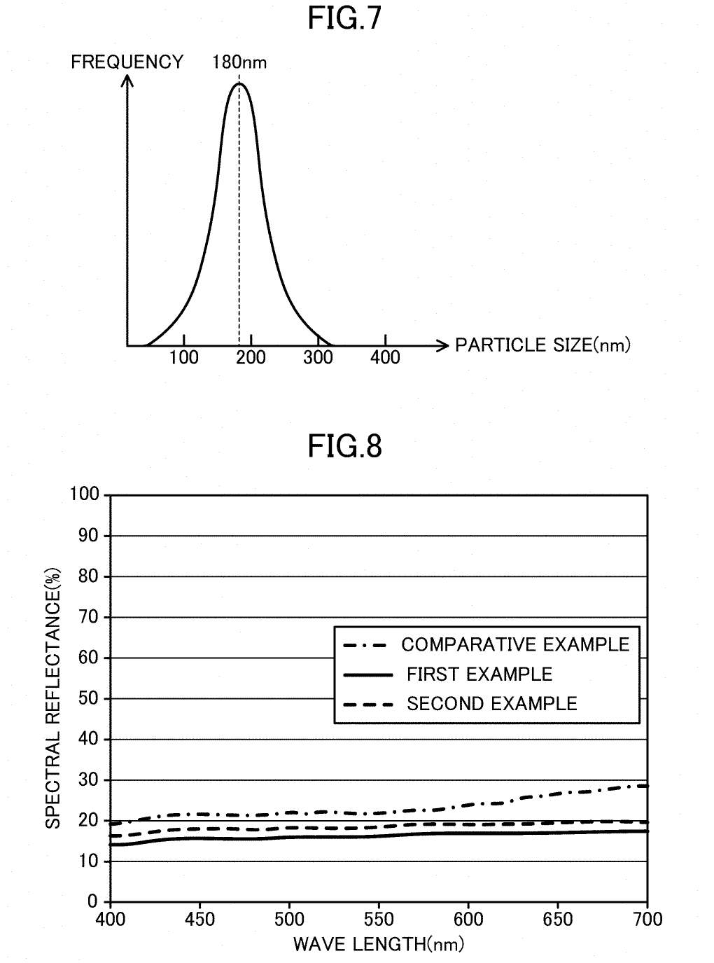

After having employed the wet-on-wet method to apply each coating, namely the black base layer, the bright layer, the colored layer, and the transparent clear layer, onto a steel product, the layers are stoved (heated at 140° C. for 20 minutes). FIG. 7 shows the particle size distribution of the fine carbon black used. As FIG. 7 shows, the fine carbon black has a particle size distribution with a sharp peak at a particle size of 180 nm. The aluminum flakes in the bright layer have a particle size ranging from 10 μm to 30 μm inclusive when viewed in plane, and a thickness ranging from 0.1 μm to 2 μm inclusive.

### Second Example

The composition of a multilayer coating film of a second example is shown in Table 2.

TABLE 2

| | | Solid | |
|---|---|---|---|
| | | Content | |
| Coating Film | | by Mass | Thickness |
| Layers | Resins and Other Components | (%) | (μm) |
| Transparent | Resin: Acid/Epoxy-Based Cured | 100 | 35 |
| Clear Layer | Acrylic Resin | | |
| Colored Layer | Resin: Acrylic-Based Resin | 99.7 | 10 |
| | Pigment: Fine Carbon Black | 0.3 | |
| | (Peak Particle Size: 180 nm) | | |
| Bright Layer | Resin: Acrylic-Based Resin | 68.0 | 2 |
| | Pigment: Fine Carbon Black | 7.0 | |
| | Bright Material: Vapor-Deposited | 25.0 | |
| | Aluminum Flakes | | |
| Base Layer | Resin: Polyester-Based Resin | 71.3 | 15 |
| | Pigment: Commercially Available | 3.6 | |
| | Carbon Black | | |
| | Pigment: Titanium Oxide | 13.7 | |
| | Extender Pigment: Barium Sulfate | 11.4 | |

In the second example, the base layer is grey, whereas the other aspects of the composition are the same as in the first example.

### Comparative Example

The composition of a multilayer coating film of a comparative example is shown in Table 3.

TABLE 3

| | | Solid | |
|---|---|---|---|
| | | Content | |
| Coating Film | | by Mass | Thickness |
| Layers | Resins and Other Components | (%) | (μm) |
| Transparent | Resin: Acid/Epoxy-Based Cured | 100 | 35 |
| Clear Layer | Acrylic Resin | | |
| Colored Layer | Resin: Acrylic-Based Resin | 99.7 | 10 |
| | Pigment: Commercially Available | 0.3 | |
| | Carbon Black | | |
| | (Peak Particle Size: 400 nm) | | |
| Bright Layer | Resin: Acrylic-Based Resin | 68.0 | 2 |
| | Pigment: Commercially Available | 7.0 | |
| | Carbon Black | | |
| | Bright Material: Vapor-Deposited | 25.0 | |
| | Aluminum Flakes | | |
| Base Layer | Resin: Polyester-Based Resin | 71.3 | 15 |
| | Pigment: Commercially Available | 3.6 | |
| | Carbon Black | | |
| | Pigment: Titanium Oxide | 13.7 | |
| | Extender Pigment: Barium Sulfate | 11.4 | |

In the comparative example, commercially available carbon black (peak particle size of 400 nm) is employed as pigment in the colored layer and the bright layer. The base layer is a grey layer. The other aspects of the composition are the same as in the first example.

—Evaluation of Multilayer Coating Film—

A multi-angle spectrophotometer (GCMS-4 by MURAKAMI COLOR RESEARCH LABORATORY CO., Ltd.) was used to measure the spectral reflectance of the multilayer coating films of the first and second examples and the comparative example. The wavelength measurement ranged from 400 nm to 700 nm. Measurement results are shown in FIG. 8.

The first and second examples have a flat (substantially constant) spectral reflectance curve over the entire wavelength of 400 nm to 700 nm, and feature no red or yellow color development. The comparative example has a spectral reflectance curve, which becomes higher at a wavelength ranging from 600 nm to 700 nm inclusive, and features red or yellow color development.

Further, the lightness of highlights (Y value)(3°) and shade (L* value)(110°) of the multilayer coating films of the first and second examples and the comparative example have been measured. (These coatings feature a huge disparity around highlights of 3°. When expressing the highlights with the L* value, however, the value of 100—which is the upper limit of the L* value—is exceeded. Therefore, the highlights are expressed with the Y value.) Results are shown in Table 4.

TABLE 4

| | Y (3°) | L* (110°) |
|---|---|---|
| First Example | 421.2 | 2.21 |
| Second Example | 290.2 | 4.67 |
| Comparative Example | 98.1 | 6.38 |

The first and second examples feature a strong contrast between highlights and shade, which shows that a color development with a strong effect of light and shade (high-contrast) has been obtained. In particular the first example, where the base layer is black, features a big difference in lightness between highlights and shade.

### DESCRIPTION OF REFERENCE CHARACTERS

1 Structure
2 Primary Particles
11 Automobile Body (Steel Plate)
12 Multilayer Coating Film
13 Electrodeposition Coating Film
14 Black Base Layer
15 Bright Layer
16 Colored Layer (Black)
17 Transparent Clear Layer
21 First Black Pigment
22 Bright Material (Aluminum Flakes)
23 Second Black Pigment (Fine Carbon Black)

1. A multilayer coating film comprising a colored layer superposed on a bright layer, the colored layer being translucent and including a black pigment dispersed in the colored layer,
the bright layer being superposed on a black base layer,
the bright layer being a coating film including a bright material,
the black pigment in the colored layer having a particle size distribution with a peak at a particle size of 200 nm or lower, and
the black pigment in the colored layer having a concentration ranging from 0.2% by mass to 0.4% by mass inclusive.

2. (canceled)

3. The multilayer coating film of claim 1, wherein
the black pigment in the colored layer is carbon black.

4. (canceled)

5. The multilayer coating film of claim 1, wherein
the bright material is aluminum flakes.

6. The multilayer coating film of claim 5, wherein
the aluminum flakes are vapor-deposited aluminum flakes.

7. (canceled)

8. The multilayer coating film of claim 1, wherein
a transparent clear layer is superposed on the colored layer.

9. A coated object comprising the multilayer coating film of claim 1.
